(19) United States
(12) Patent Application Publication
(10) Pub. No.: US 2017/0200831 A1
(43) Pub. Date: Jul. 13, 2017

(54) THIN-FILM TRANSISTOR, ARRAY SUBSTRATE, AND DISPLAY APPARATUS CONTAINING THE SAME, AND METHOD FOR FABRICATING THE SAME

(71) Applicants: BOE TECHNOLOGY GROUP CO., LTD, Beijing (CN); HEFEI XINSHENG OPTOELECTRONICS TECHNOLOGY CO., LTD., Hefei (CN)

(72) Inventors: Yudong LIU, Beijing (CN); Xiong XIONG, Beijing (CN); Chengying CAO, Beijing (CN); Hui WANG, Beijing (CN); Lin LIN, Beijing (CN); Fangfang WU, Beijing (CN)

(21) Appl. No.: 15/325,488

(22) PCT Filed: May 20, 2016
(86) PCT No.: PCT/CN2016/082885

§ 371 Date: Jan. 11, 2017

(30) Foreign Application Priority Data
Aug. 6, 2015 (CN) 201510478094.8

(51) Int. Cl. H01L 29/786; H01L 29/423; H01L 29/417

(52) U.S. Cl. CPC H01L 29/78618; H01L 29/78603; H01L 29/41733; H01L 29/42384; H01L 29/4236; H01L 27/124

(57) ABSTRACT

The present disclosure provides a thin-film transistor. The thin-film transistor includes a substrate including at least one trench; at least one electrode in each of the at least one trench, the at least one electrode being one or more of a gate electrode, a source electrode, and a drain electrode; and an active layer over the at least one electrode.

### CROSS-REFERENCES TO RELATED APPLICATIONS

This PCT patent application claims priority of Chinese Patent Application No. 201510478094.8, filed on Aug. 6, 2015, the entire content of which is incorporated by reference herein.

### TECHNICAL FIELD

The present invention generally relates to the display technologies and, mare particularly, relates to a thin-film transistor (HT), an array substrate and a display apparatus containing the TFT, and a method for fabricating the TFT.

### BACKGROUND

Thin-film transistor liquid crystal displays (TFT-LCDs) have several advantages such as being thin and of lower power consumption, and having little or no radiation. TFT-LCDs have been widely used. A TFT-LCD often includes an array substrate, which includes a plurality of TFTs. For example, an a-Si (amorphous silicon) TFT often includes a gate electrode, a gate insulating layer, an i-a-Si (intrinsic silicon) layer, an n+a-Si (doped a-Si) layer, a source and drain electrode, and an insulating protection layer. The gate electrode and/or the source and drain electrode in such a structure often cause section differences, e.g., retarded regimes, in the fabrication and result in atoms of the intermediate layers to climb up during deposition. As a result, the films may be susceptible to cracking. Film deposition may thus be more difficult and risky. Line defects can be easily formed in such structures. High section differences may reduce the flatness of the array substrate. In this case, even if a planarization layer is applied on the array substrate, rubbing Mura can still be formed easily.

On the other hand, to form metal wiring in an existing array substrate, a metal film is often deposited and a patterning process, e.g., including a photolithography process and an etching process, is performed afterwards to form a photoresist pattern. The etching process is often a wet etching to remove the exposed portions of the metal film. A desired metal pattern can thus be formed. To fabricate, such an array substrate, five masks and their related fabrication steps are often required, which increases the complexity of the fabrication process. Each additional mask adds more complexity to the fabrication process and greatly increases the takt time (the average time required for fabricating one array substrate). The fault-tolerance rate of the fabrication process can be decreased and the fabrication cost of an array substrate can be increased.

### BRIEF SUMMARY

The present disclosure provides a TFT, an array substrate and a display apparatus containing the TFT, and a method for fabricating the TFT. The section differences in the film structure of a top-gated TFT can be reduced.

One aspect of the present disclosure includes a thin-film transistor. The thin-film transistor includes a substrate including at least one trench; at least one electrode in each of the at least one trench, the at least one electrode being one or more of a gate electrode, a source electrode, and a drain electrode; and an active layer over the at least one electrode.

Optionally, a depth of a trench is less than twice a thickness of the at least one electrode in the trench.

Optionally, the substrate includes two trenches, a source electrode being in a first trench and a drain electrode being in a second trench.

Optionally, the substrate includes one trench, a agate electrode being in the one trench.

Optionally, the source electrode fills up the first trench, and the drain electrode fills up the second trench.

Optionally, a depth of the first trench is substantially equal to a depth of the second trench.

Optionally, the depth of a trench is substantially equal to the thickness of the at least one electrode in the trench.

Optionally, a first ohmic contact layer is between the source electrode and the active layer, a pattern of the source electrode is same as a pattern of the first ohmic contact layer; and a second ohmic contact layer is between the drain electrode and the active layer, a pattern of the drain electrode is same as a pattern of, the second ohmic contact layer.

Optionally, the first ohmic contact layer and the second ohmic contact layer are made of a semiconductor material with a resistivity lower than the active layer.

Another aspect of the present disclosure provides an array substrate. The array substrate includes one or more of the disclosed thin-film transistors.

Another aspect of the present disclosure provides a display apparatus. The display apparatus includes one or more of the disclosed array substrates.

Another aspect of the present disclosure provides a method for forming a thin-film transistor. The method includes: forming at least one trench in a substrate; forming at least one electrode in each of the at least one trench, the at least one electrode comprising one or more of a source electrode, a drain electrode, and a gate electrode; and forming an active layer over the at least one electrode.

Optionally, a depth of a trench being less than twice a thickness of the at least one electrode in the trench.

Optionally, forming the at least one trench includes: forming a photoresist pattern on the substrate, regions of the substrate exposed by the photoresist pattern corresponding to the at least one trench; and performing an etching process to remove the regions of the substrate exposed by the photoresist pattern to form the at least one trench in the substrate.

Optionally, forming the at least one electrode in a trench further includes: forming a conductive layer in the at least one trench and on the substrate; and removing the photoresist pattern and portions of the conductive layer outside the trench and on the substrate.

Optionally, the thin-film transistor includes a source electrode in a first trench and a drain electrode in a second trench, a process for forming the first trench and the second trench including: forming a conductive layer in the first trench, in the second trench, and on the substrate; forming a doped a-Si layer on the conductive layer; and removing the photoresist pattern, portions of the conductive layer on the photoresist pattern, and portions of the doped a-Si layer on the conductive layer to maintain portions of the conductive layer and portions of the doped layer in the first trench and in the second trench, a portion of the doped a-Si layer in the first trench being a first ohmic contact layer, a portion of the doped a-Si layer in the second trench being a second ohmic contact layer.

Optionally, the thin-film transistor includes a gate electrode in one trench, a process to form the one electrode includes: forming a conductive layer in the one trench and on the photoresist pattern; removing the photoresist pattern and portions of the conductive layer on the photoresist pattern to maintain a portion of the conductive layer in the one trench; and forming a gate insulating layer covering the conductive layer and the substrate.

Optionally, a depth of the first trench is substantially equal to a depth of the second trench.

Optionally, a depth of the first trench is substantially equal to the thickness of the first electrode, and a depth of the second trench is substantially equal to the thickness of the second electrode.

Optionally, forming the conductive layer and the doped a-Si layer includes: depositing the conductive layer and the doped, a-Si layer along a direction substantially perpendicular to the substrate.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a cross-sectional view of an exemplary TFT according to the disclosed embodiments of the present disclosure;

FIG. 2 illustrates a process flow of an exemplary method for forming a TFT according to the disclosed embodiments of the present disclosure;

FIG. 3 (a)-(f) each illustrates a cross-sectional view of a TFT structure at various stages when forming an exemplary TFT according to the embodiments of the present disclosure; and

FIG. 4 illustrates a cross-sectional view of another exemplary TFT according to the disclosed embodiments of the present disclosure.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

One aspect of the present disclosure provides a TFT. The TFT includes a substrate including a first trench and a second trench; a first electrode in the first trench and a second electrode in the second trench, the first electrode including at least a source electrode, and the second electrode including at least a drain electrode; and an active layer on and contacting the first electrode and the second electrode. A depth of the first trench is less than twice a thickness of the first electrode, and a depth of the second trench is less than twice a thickness of the second electrode.

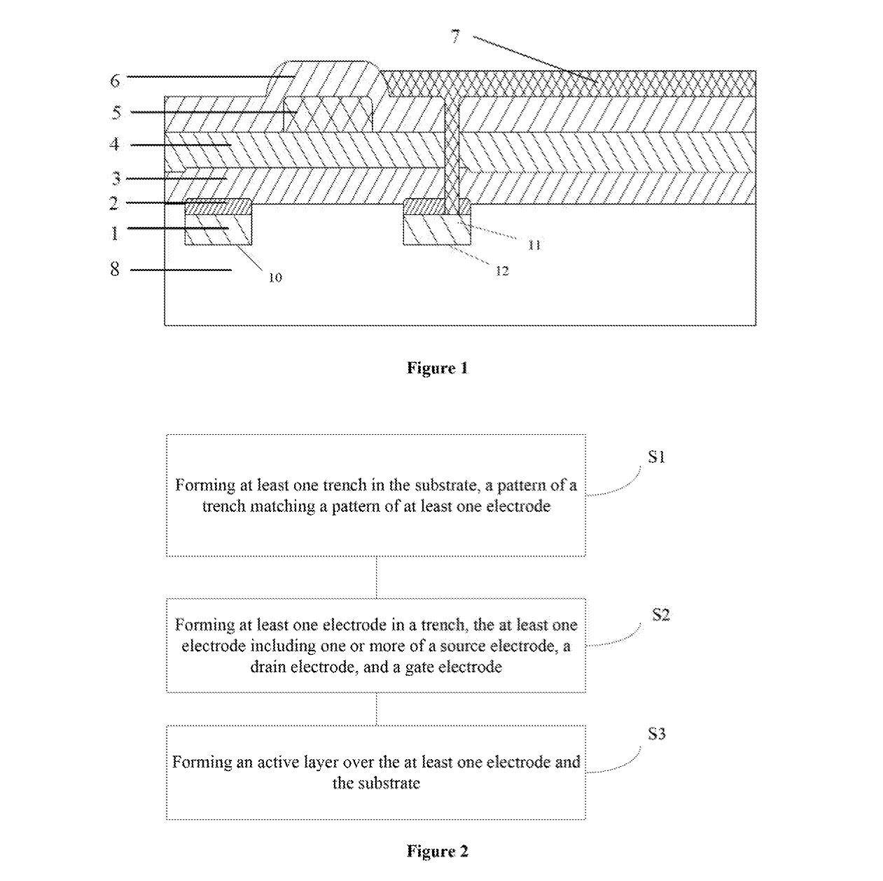

FIG. 1 illustrates an exemplary TFT provided by the present disclosure. As shown in FIG. 1, the TFT may include a substrate 8. A first trench 10 and a second trench 12 may be formed in the substrate 8. The first trench 10 may be a recess region positioned at the left side in the substrate 8 shown in FIG. 1. The second trench 12 may be a recess region positioned at the right in the substrate 8 shown in FIG. 1. As used herein, the terms “left” and “right” are only used to describe the relative positions with respect to the viewing direction towards FIG. 1. For illustrative purposes, element: numbers 10 and 12 are indicated at the bottoms of the first trench 10 and the second trench 12 to differentiate the source electrode 1 and the drain electrode 11 formed in the first trench 10 and the second trench 12.

The source electrode 1 of the TFT may be disposed in the first trench 10. The shape or pattern of the first trench 10 may match the pattern or shape of the source electrode 1. The drain electrode 11 of the TFT may be disposed in the second trench 12. The shape or pattern of the second trench 12 may match the pattern or shape of the drain electrode 11. The term “match” may refer to having the same shape at a horizontal cross-section at a corresponding depth. For example, the shape of a horizontal cross-section of the first/second trench at a certain depth may be the same as the shape of the horizontal cross-section at the corresponding depth of the source/drain. In some embodiments, the source electrode 1 may fill up the first trench 10 and the drain electrode 11 may fill up the second trench 12. In the present disclosure, the source and the drain electrode may be made of any suitable conductive materials such as one or more of metal and metal alloys. It should be noted that, in the present disclosure, for illustrative purposes, a trench and the electrode that is formed in the trench may overlap in the drawings. The description of different objects may be referred to the description of the embodiments.

In a TFT provided by the embodiments of the present disclosure, the first trench and the second trench may be formed in the substrate. The shape of the first trench may match the pattern or shape of the source electrode, and the shape of the second trench may match the pattern or shape of the drain electrode. A first electrode may be disposed in the first trench, and a second electrode may be disposed in the second trench. An active layer may be disposed on the first electrode and the second electrode and contacting the first electrode and the second electrode. The first electrode may include at least the source electrode, and the second electrode may include at least the drain electrode. The depth of the first trench may be less than twice the thickness of the first electrode, and the depth of the second trench may be less than twice the thickness of the second electrode. Compared to an existing TFT, which often does not include trenches in the substrate for receiving electrodes, section differences, e.g., retarded regimes, in the films on the source electrode and the drain electrode may be reduced. Cracking of the films caused by the high section differences may be reduced or prevented. The difficulty and risk of depositing films can be lowered. Line defects can be reduced or avoided, and rubbing Mura may be reduced. Fabrication yield of the TFTs can be improved.

Further, to reduce the contact resistance between the source electrode and the active layer, and between the drain electrode and the active layer, the source electrode may be covered by a first ohmic contact layer, and the drain electrode may be covered by a second ohmic contact layer. The first ohmic contact layer and the second ohmic contact may be made of a semiconductor material and may each have a lower resistivity than the active layer. The pattern of the first ohmic contact layer may correspond to the pattern of the source electrode. The pattern of the second ohmic contact layer may correspond to the pattern of the drain electrode. The term “correspond” may refer to having same and overlapping patterns. Thus, only one mask and its related fabrication step are needed to form the first electrode that includes the source electrode and the first ohmic contact layer and the second electrode that includes the dram electrode and the second ohmic contact layer. Compared to an existing TFT, the fabrication process to form the disclosed TFT may include less fabrication steps, e.g., an additional mask and its related fabrication steps for forming the first ohmic contact layer and the second ohmic contact layer can be omitted. The specific fabrication process to form the disclosed TFT is further illustrated herein.

Specifically, as shown in FIG. 1, the first ohmic contact layer and the second ohmic contact layer may be element 2. The active layer may be element 3. The first ohmic contact layer and the second ohmic contact layer, i.e., element 2, may be made of doped a-Si or n+a-Si. The active layer, i.e., element 3, may be made of intrinsic a-Si or i-a-Si. In the disclosure, the first ohmic contact layer and the second ohmic contact layer my also be referred as the n+a-Si layer 2, and the active layer may also be referred as the i-a-Si layer 3.

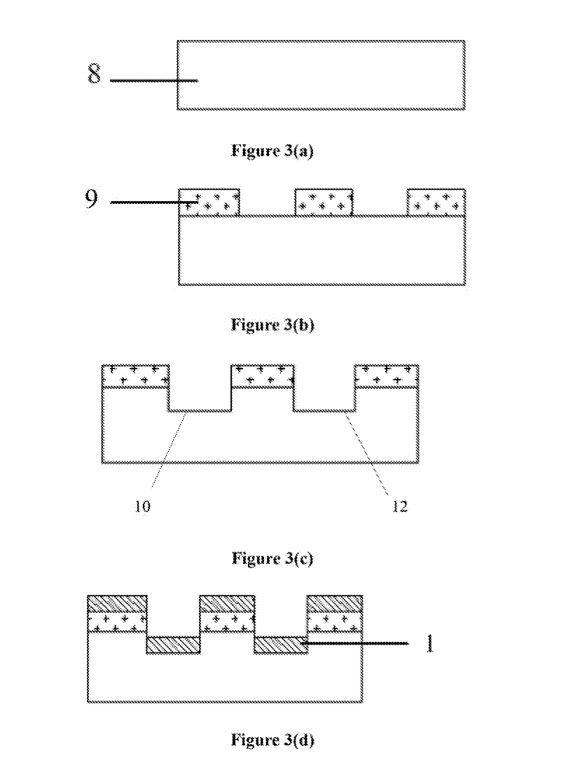

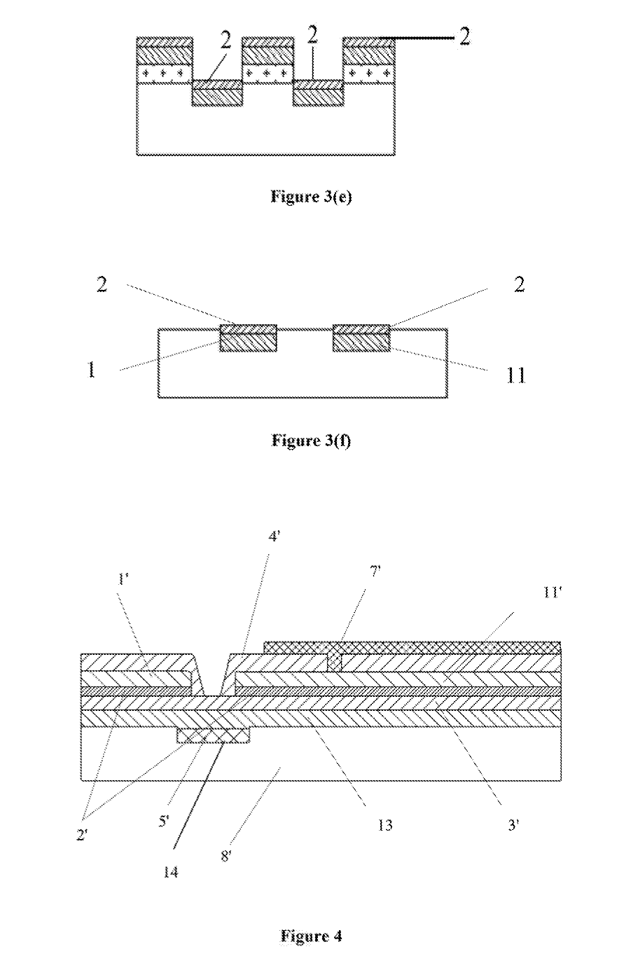

In various embodiments of the present disclosure, the first electrode may also only include the source electrode 1 and the second electrode may also only include the drain electrode 11. The active layer may be formed on the source electrode 1, the drain electrode 11, and the substrate directly. That is, optionally, the first ohmic contact layer and the second ohmic contact may not be formed on the source electrode 1 and the drain electrode 11. For viewing simplicity and illustrative purposes, in FIGS. 1 and 3 of the present disclosure, the first electrode may be represented by the source electrode and the second electrode may be represented by the drain electrode 11.

In some embodiments, the disclosed TFT may be a top-gated TFT, as shown in FIG. 1. In some other embodiments, the disclosed TFT may also be other types of TFTs. The structure of the TFT and the fabrication process to form the TFT may be determined or adjusted according to different applications and designs, and should not be limited by the embodiments of the present disclosure.

As shown in FIG. 1, the disclosed TFT may further include an insulating layer 4 formed on the i-a-Si layer 3, a gate electrode 5 formed on the insulating layer 4, and a gate electrode protection layer 6 formed over the gate electrode 5. The gate electrode protection layer 6 may cover the gate electrode 5. A pixel electrode 7 may be formed on the gate electrode protection layer 6. The pixel electrode 7 may be electrically and physically connected to the drain electrode 11 or drain pattern through a via hole.

In some embodiments, the thickness of the first electrode may be substantially equal to the depth of the first trench 10, and the thickness of the second electrode ma be substantially equal to the depth of the second trench 12. The active layer, i.e,, the i-a-Si layer 3, may be disposed on the substrate 8 with desired flatness. That is, the first electrode and the second electrode may introduce little or no section differences, in addition, in some embodiments, the depth of the first trench 10 may be substantially equal to the depth of the second trench 12. Section differences, caused by difference in depths between the first trench 10 and the second trench 12, may be avoided or reduced.

FIG. 4 illustrates the cross-sectional view of another exemplary TFT provided by the present disclosure.

As shown in FIG. 4, a substrate 8′ may include a trench 14 may be formed in a surface, e.g., a top surface, of the substrate 8′. An electrode 5′ may be formed in the trench 14. The trench 14 may be a recess region in the substrate 8′. The electrode 5′ may include at least a gate electrode of a TFT. The gate electrode may be made of poly-silicon, metals, or metal alloys. The depth of the trench 14 may be less than twice the thickness of the electrode 5′. A gate insulating layer 13 may be formed on the substrate 8 to cover the electrode 5′ and the substrate 8′. An active layer 3′ may be formed on the gate insulating layer 13. An ohmic contact layer 2 may be formed on the active layer 3′. The active layer 3′ may be made of intrinsic a-Si or i-a-Si. The ohmic contact layer 2′ may include a first ohmic contact layer and a second ohmic contact layer. A source electrode 1′ may be formed on the first ohmic contact layer, and a drain electrode 11′ may be formed on the second ohmic contact layer. The source electrode and the first ohmic contact layer 2′ may be located on the left side of the TFT shown in FIG. 4. The drain electrode 11′ and the second ohmic contact layer 2′ may be located on the right side of the TFT shown on the right side of FIG. 4. It should be noted that, the terms “left” and “right” may only be used to describe the relative positions with respect to the viewing direction towards FIG. 4.

Further, the TFT shown in FIG. 4 may also include an insulating layer 4′ on the source electrode 1′, the drain electrode 11′ and the active layer 3′. The insulating layer 4′ may be made of any suitable materials. A pixel electrode 7′ may be formed on the insulating layer 4′. The pixel electrode 7′ may be electrically connected to the drain electrode 11′ through a via.

The pattern or shape of the trench 14 may match the pattern or shape of the electrode 5′. In some embodiments, the electrode 5′ may fill up the trench 14. In some embodiments, the electrode 5′ may include only the gate electrode of a TFT. In some embodiments, the thickness of the electrode 5′ may be substantially equal to the depth of the trench 14. The fabrication, functions, materials, and patterns of other layers may be referred to previous description of the present disclosure and are not repeated herein.

In some embodiments, the disclosed TFT may be a bottom-gated TFT.

By disposing the gate electrode of the TFT in a trench 14 in the substrate, layers or films formed on the substrate and the gate electrode may have improved flatness. Section differences, caused by difference in thicknesses of different layers, may be reduced. The difficulty and risk of depositing films can be lowered. Line defects can be reduced or avoided, and rubbing Mura may be reduced. Fabrication yield of the TFTs can be improved.

Another aspect of the present disclosure provides an array substrate. The array substrate may include one or more of the disclosed TFTs. It should be noted that, the disclosed array substrate may be an array substrate used for LCDs, an array substrate used for organic light-emitting diode (OLED) displays, or any other suitable displays devices.

Another aspect of the present disclosure provides a display apparatus. The display apparatus may incorporate one or more of the disclosed TFTs and/or the disclosed array substrates. The display apparatus according to the embodiments of the present disclosure can be used in any products with display functions such as a television, an electronic paper, a digital photo frame, a mobile phone, a computer, a navigation device, and a tablet computer.

Another aspect of the present disclosure provides a method for forming the disclosed TFT. The method includes fanning at least one trench in a substrate; forming at least one electrode in a trench, the at least one electrode including one or more of a source electrode, a drain electrode, and a gate electrode. A depth of a trench being less than twice a thickness of the at least one electrode in the trench; and forming an active layer on the at least one electrode.

FIG. 2 illustrates an exemplary process flow of the disclosed method. FIGS. 3(a)-(f) illustrate cross-sectional views of a source electrode and a drain electrode in various stages during the fabrication process when the to-be-formed TFT includes two trenches, one containing the source electrode and the other containing the drain electrode. For illustrative purposes, only the source electrode, the drain electrode, and related parts of one TFT are shown. Parts with the same pattern or shade represent the same object or being made of a same material. The description of the fabrication process may be based on the fabrication of one TFT as an example. The fabrication process may include steps S1-S3. In FIG. 3(a)-(f), parts with the same shade are made of a same material.

In step S1, at least one trench may be formed in a top surface of a substrate. The pattern or shape of a trench may match the pattern or shape of at least one electrode.

In some embodiments, the TFT may be a top-gated TFT and may include two trenches, i.e., a first trench 10 and a second trench 12, formed in a top surface of a substrate. The pattern or shape of the first trench 10 may match the pattern of the source electrode 1. The pattern or shape of the second trench 12 may match the pattern of the drain electrode 11.

It should be noted that the top surface may also be referred as the surface or a surface that is designed for forming parts of the TFT.

For example, FIGS. 3(a)-(f) illustrate cross-sectional views of a source electrode 1 and a drain electrode 11 in various stages during the fabrication process when the to-be-formed TFT includes two trenches. As shown in FIG. 3(a), a substrate 8 may be provided. The substrate 8 may include a surface with desired flatness. The substrate 8 may be made of any suitable materials such as one or more of glass and organic materials.

Further, in step S1, as shown in FIG. 3(b), a photoresist pattern 9 may be formed on the substrate 8. Regions of the substrate 8 not covered or exposed by the photoresist pattern 9 may correspond to the predetermined locations of the first trench 10 and the second trench 12. The process to form the photoresist pattern 9 may include forming a photoresist layer on the substrate 8, exposing and developing the photoresist layer, and removing portions the photoresist layer corresponding to the first trench 10 and the second trench 12.

Further, a suitable etching process, e.g., a reactive-ion etching (RIE) process, may be performed on the regions corresponding to the first trench 10 and the second trench 12, to form the first trench 10 and the second trench 12, as shown in FIG. 3(c). In practice, the photoresist pattern 9 may be used as the etch mask The processing parameters of the RIE process may be optimized so that the RIF process may have a desirably high etch selectivity. That is, only a portion of the photoresist pattern 9 would be consumed to etch each of the first trench 10 and the second trench 12 down to a desired depth for containing the corresponding receiving electrode and the n+a-Si layer. For example, the depth of the first trench 10 and the second trench 12 may be about 5000 Å.

In step S2, at least one electrode may be formed in a trench. The at least one electrode may include one or more of a source electrode, a drain electrode, and a gate electrode.

In some embodiments, the TFT may be a top-gated TFT with a first trench 10 and a second trench 12. A first electrode may be formed in the first trench 10 and a second electrode may be formed in the second trench 12. The first electrode may include at least a source electrode 1 and the second electrode may include at least a drain electrode 11. The depth of the first trench 10 may be less than twice the thickness of the first electrode. The depth of the second trench 12 may be less than twice the thickness of the second electrode. Thus, the section differences in the films thrilled on the source electrode 1 and the drain electrode 11′ can be reduced.

For example, in this case, in step S2, a conductive layer may be formed in the first trench 10, in the second trench 12, and on the photoresist pattern 9, as shown in FIG. 3(d). The conductive layer may be made of one or more of metal and alloys. Portions of the conductive layer may be formed on the photoresist pattern 9, and potions of the conductive layer may be formed in the first trench 10 and the second trench 12.

Further, optionally, a doped a-Si layer, i.e., n+a-Si layer, may be formed on the conductive layer, as shown in FIG. 3(e).

When forming or depositing the n+a-Si layer, the direction of the deposition may be controlled to be the direction that is substantially perpendicular to the substrate 8. In some embodiments, it is desired that the deposited materials or target materials, i.e., the materials for forming the conductive layer and the n+a-Si layer, may still be deposited along the direction that is substantially perpendicular to the substrate 8 after the surface of the target materials exceeds the surface of the substrate 8. Thus, adherence of target materials on the sidewalls of the photoresist pattern 9 can be avoided.

Further, the photoresist pattern 9, the conductive layer on the photoresist pattern 9, and the n+a-Si layer on the conductive layer may be removed. That is, the photoresist pattern 9 may be removed through a suitable process, and the conductive layer and the n+a-Si layer on the photoresist pattern 9 may be removed accordingly, as shown in FIG. 3(f). The removal of the photoresist pattern 9 may include using a suitable stripper to remove the photoresist pattern 9. Portions of the conductive layer 1 and portions of the n+a-Si layer 2 in the first trench 10 and the second trench 12 may remain. That is, the source electrode 1 and the first ohmic contact layer 2 may be formed in the first trench 10, and the drain electrode 11 and the second ohmic 2 contact layer may be formed in the second trench 12. The thickness of the photoresist pattern 9 may be about three times the total thickness of the conductive layer 1 and the n+a-Si layer 2 to implement desirable stripping performance. It Should be noted that, the thickness of the photoresist pattern 9 may only be close to three times the total thickness of the conductive layer 1 and the n+a-Si layer 2, and needs not be exact.

In step S3, an active layer may be formed over the at least one electrode and the substrate.

In some embodiments, the TFT may include a first electrode in the frit trench and 10 a second electrode in the second trench 12. In this case, in step S3, the fabrication process to form the active layer 3 may include forming an i-a-Si layer on the n+a-Si layer 2 and the substrate 8.

It should be noted that, in the embodiments of the present disclosure, the first electrode may only include the source electrode 1, and the second electrode may only include the drain electrode 11. In this case, the active layer 3, i.e., the i-a-Si layer, may be formed on the source electrode 1, the drain electrode 11, and the substrate 8 directly.

Further, the fabrication process may further include forming an insulating layer 4 on the active layer, a gate electrode 5 on the insulating layer 4, and a gate electrode protection layer 6 on the insulating layer 4 to cover the gate electrode 5. The fabrication process may further include forming a pixel electrode 7 on the gate electrode protection 6, the pixel electrode 7 being connected to the source electrode 1 or the drain electrode 11 through a via hole. The formed TFT according to the fabrication process is illustrated in FIG. 1.

In some embodiments, the thickness of the first electrode may be substantially equal to the depth of the first trench 10, and the thickness of the second electrode may be substantially equal to the depth of the second trench 12. Thus, the active layer formed on the substrate 8, i.e., the i-a-Si layer 3, may have desired or improved flatness. That is, the first electrode and the second electrode may introduce little or no section differences. In addition, in some embodiments, the depth of the first trench 10 may be substantially equal to the depth of the second trench 12 to avoid section differences caused by differences between the depth of the first trench 10 and the depth of the second trench 12.

In certain embodiments, the disclosed TFT may be a bottom-gated TFT, as shown in FIG. 4. In this case, a trench 14 may be formed in the substrate 8′ in step S1. An electrode 5′, e.g., a gate electrode 5′, may be formed in the trench 14 in step S2. A gate insulating layer 13 may be formed to cover the gate electrode. The gate electrode may be made of any suitable materials, e.g., metal, metal alloys, or poly-silicon. An active layer 3′ may be formed on the gate insulating layer 13 or over the electrode 5′ in step S3. A source electrode 1′ and a drain electrode 11′ may be formed on the gate insulating layer 13, where a first ohmic contact layer is positioned between the source electrode 1′ and the active layer 3′ and a second ohmic contact layer is positioned between the drain electrode 11′ and the active layer 3′. The first ohmic contact layer and the second ohmic contact layer may together be referred as the element 2′. An insulating layer 4′ may be formed on the source electrode 1′ and the drain electrode 11′. A pixel electrode 7′ may be formed on the insulating layer 4′ and be electrically connected with the drain electrode 11′ through a via. Details of the fabrication of the TFT shown in FIG. 4 may be referred to previous description and are not repeated herein. For illustrative purposes, in the present disclosure, the electrode may be represented as the gate electrode 5′ in FIG. 4 and the related description.

By using the method for forming the TFT provided by the present disclosure, the first trench and the second trench may first be formed in the substrate. The shape of the first trench may match the pattern of the source electrode, and the shape of the second trench may match the pattern of the drain electrode. The first electrode may be formed in the first trench, and the second electrode may be formed in the second trench. The first electrode may include at least the source electrode, and the second electrode may include at least the drain electrode. The depth of the first trench may be less than twice the thickness of the first electrode, and the depth of the second trench may be less than twice the thickness of the second electrode. Compared to an existing TFT fabrication method, which often does not include forming trenches in the substrate that contain receiving electrodes, section differences in the films of a top-gated TFT caused by the source electrode and the drain electrode, in a TFT fabricated by the disclosed method, may be reduced. Cracking of the films on the source electrode and the drain electrode regions caused by the high section differences ma be reduced or prevented. The difficulty and risk of depositing films can be lowered. Line defects can be reduced or avoided, and rubbing Mura may be reduced. Fabrication yield of the TFTs can be improved. Also, the fabrication process to form the first electrode and the second electrode may include first forming the photoresist pattern and the trenches, and forming the conductive layer and the n+a-Si layer through deposition, photolithography, and stripping processes. Only one mask and its related fabrication step are required for the abovementioned fabrication process. Compared to an existing TFT fabrication method, less fabrication steps are needed. That is, only one mask and its related fabrication steps are needed to form the first electrode that includes the source electrode and the first ohmic contact layer and the second electrode that includes the drain electrode and the second ohmic contact layer. Takt time can be reduced.

Description of the present invention includes explanation of a great number of specific details. However, it should be noted that, the embodiments of the present disclosure may also be practiced without these specific details. In some embodiments, well-known methods, structures, and processes are not illustrated in detail to more clearly define the present disclosure.

Unless specified, the technical terms or scientific terms used in this disclosure should have ordinary meanings/definitions to those skilled in the art. In the disclosure, “first”, “second”, and similar terms do not indicate any order, quantity, or significance, but only be used to distinguish different components. “Comprising”, “with”, and other similar terms indicate that, the word appears in front of the term Covers the object appears behind the term and their equivalents, but does not exclude other elements or objects. “Connection”, “connected”, and other similar terms are not limited to Physical or mechanical connections, but may also include electrical connections, directly and indirectly.

It should be understood that the above embodiments disclosed herein are exemplary only and not limiting the scope of this disclosure. Without departing from the spirit and scope of this invention other modifications, equivalents, or improvements to the disclosed embodiments are obvious to those skilled in the art and are intended to be encompassed within the scope of the present disclosure.

1-20. (canceled)

21. A thin-film transistor, comprising:
a substrate including at least one trench;
at least one electrode in each of the at least one trench, the at least one electrode being one or more of a gate electrode, a source electrode, and a drain electrode; and
an active layer over the at least one electrode.

22. The thin-film transistor according to claim 21, wherein:
a depth of a trench is less than twice a thickness of the at least one electrode in the trench.

23. The thin-film transistor according to claim 22, wherein the substrate includes two trenches, a source electrode being in a first trench and a drain electrode being in a second trench.

24. The thin-film transistor according to claim 22, wherein the substrate includes one trench, a gate electrode being in the one trench.

25. The thin-film transistor according to claim 23, wherein the source electrode fills up the first trench, and the drain electrode fills up the second trench.

26. The thin-film transistor according to claim 23, wherein a depth of the first trench is substantially equal to a depth of the second trench.

27. The thin-film transistor according to claim 21, wherein the depth of a trench is substantially equal to the thickness of the at least one electrode in the trench.

28. The thin-film transistor according to claim 23, wherein:
a first ohmic contact layer is between the source electrode and the active layer, a pattern of the source electrode is same as a pattern of the first ohmic contact layer; and
a second ohmic contact layer is between the drain electrode and the active layer, a pattern of the drain electrode is same as a pattern of the second ohmic contact layer.

29. The thin-film transistor according to claim 28, wherein the first ohmic contact layer and the second ohmic contact layer are made of a semiconductor material with a resistivity lower than the active layer.

30. An array substrate, including one or more thin-film transistors according to claim 21.

31. A display apparatus, comprising one or more of the array substrates according to claim 30.

32. A method for forming a thin-film transistor, comprising:
forming, at least one trench in a substrate;
forming at least one electrode in each of the at least one trench, the at least one electrode comprising one or more of a source electrode, a drain electrode, and a gate electrode; and
forming an active layer over the at least one electrode.

33. The method according to claim 32, wherein a depth of a trench being less than twice a thickness of the at least one electrode in the trench.

34. The method according to claim 32, wherein for the at least one trench includes:
forming a photoresist pattern on the substrate, regions of the substrate exposed by the photoresist pattern corresponding to the at least one trench; and
performing an etching process to remove the regions of the substrate exposed by the photoresist pattern to form the at least ogre trench in the substrate.

35. The method according to claim 32, wherein forming the at least one electrode in a trench further comprising:
forming a conductive layer in the at least one trench and on the substrate; and
removing the photoresist pattern and portions of the conductive layer outside the trench and on the substrate.

36. The method according to claim 35, wherein the thin-film transistor includes a source electrode in a first trench and a drain electrode in a second trench, a process for forming the first trench and the second trench including:
forming a conductive layer in the first trench, in the second trench, and on the substrate;
forming a doped a-Si layer on the conductive layer; and
removing the photoresist pattern, portions of the conductive layer on the photoresist pattern, and portions of the doped a-Si layer on the conductive layer to maintain portions of the conductive layer and portions of the doped a-Si layer in the first trench and in the second trench, a portion of the doped a-Si layer in the first trench being a first ohmic contact layer, a portion of the doped a-Si layer in the second trench being a second ohmic contact layer.

37. The method according to claim 35, wherein the thin-film transistor includes a gate electrode in one trench, a process to form the one electrode includes:
forming a conductive layer in the one trench and on the photoresist pattern;
removing the photoresist pattern and portions of the conductive layer on the photoresist pattern to maintain a portion of the conductive layer in the one trench; and
forming a gate insulating layer covering, the conductive layer and the substrate.

38. The method according to claim 36, wherein a depth of the first trench is substantially equal to a depth of the second trench.

39. The method according to claim 36, wherein a depth of the first trench is substantially equal to the thickness of the first electrode, and a depth of be second trench is substantially equal to the thickness of the second electrode.

40. The method according to claim 36, wherein forming the conductive layer and the doped a-Si layer includes:
depositing the conductive layer and the doped a-Si layer along a direction substantially perpendicular to the substrate.
